(19) United States
(12) Patent Application Publication
(10) Pub. No.: US 2026/0006970 A1
(43) Pub. Date: Jan. 1, 2026

(54) DISPLAY DEVICE, METHOD OF MANUFACTURING DISPLAY DEVICE AND ELECTRONIC DEVICE INCLUDING DISPLAY DEVICE

(71) Applicant: Samsung Display Co., LTD., Yongin-si (KR)

(72) Inventors: Hui Won YANG, Yongin-si (KR); Sun PARK, Yongin-si (KR); Kyung Rock SON, Yongin-si (KR); Chi Hun WON, Yongin-si (KR); Jae Bok YOO, Yongin-si (KR); Jae Phil LEE, Yongin-si (KR)

(73) Assignee: Samsung Display Co., LTD., Yongin-si (KR)

(21) Appl. No.: 19/181,679

(22) Filed: Apr. 17, 2025

(30) Foreign Application Priority Data
Jun. 27, 2024 (KR) 10-2024-0084747

(51) Int. Cl. H10H 29/80; H10H 29/01; H10H 29/856

(52) U.S. Cl. CPC H10H 29/8325; H10H 29/012; H10H 29/856

(57) ABSTRACT

A display device includes a display element layer disposed on a substrate. The display element layer includes an anode electrode and a cathode electrode; a first reflective electrode disposed on the anode electrode; a second reflective electrode disposed on the cathode electrode; a light emitting element including a first semiconductor layer, a second semiconductor layer, and an insulative film; a first transparent electrode directly electrically connecting the second semiconductor layer to the first reflective electrode; and a second transparent electrode directly electrically connecting the first semiconductor layer to the second reflective electrode.

### CROSS-REFERENCE TO RELATED APPLICATION(S)

This application claims priority to and benefits of Korean patent application No. 10-2024-0084747 under 35 U.S.C. § 119 filed on Jun. 27, 2024 in the Korean Intellectual Property Office, the entire contents of which are incorporated herein by reference.

### BACKGROUND

### 1. Technical Field

The disclosure generally relates to a display device, a method of manufacturing a display device, and an electronic device including a display device.

### 2. Description of the Related Art

With the development of information technologies, the importance of a display device which is a connection medium between a user and information increases. Accordingly, display devices such as a liquid crystal display device, an organic light emitting display device, and an inorganic light emitting display device are increasingly used.

Cracks may be generated in a light emitting element formed in transferring and bonding processes of the light emitting element. These cracks may generate a path through which a leakage current flows, and a defect of a display device due to the leakage current may occur.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device, a method of manufacturing a display device, and an electronic device including a display device, in which a path through which a leakage current flows is blocked inside of a light emitting element.

In accordance with an aspect of the disclosure, a display device may include a display element layer disposed on a substrate, wherein the display element layer may include an anode electrode and a cathode electrode; a first reflective electrode disposed on the anode electrode; a second reflective electrode disposed on the cathode electrode; a light emitting element including a first semiconductor layer, a second semiconductor layer, and an insulative film; a first transparent electrode directly electrically connecting the second semiconductor layer to the first reflective electrode; and a second transparent electrode directly electrically connecting the first semiconductor layer to the second reflective electrode.

The insulative film may include a first opening and a second opening. The second semiconductor layer may be exposed in the first opening, and the first semiconductor layer may be exposed in the second opening.

The first opening and the second opening may face in a same direction.

The display device may further include a passivation layer disposed on the first reflective electrode, the second reflective electrode, an inside of the second opening, and the light emitting element. The passivation layer may directly contact the insulative film in the second opening.

The passivation layer may include a third opening overlapping the first opening and a fourth opening disposed inside of the second opening.

The first transparent electrode and the second transparent electrode may be disposed on the passivation layer. The first transparent electrode may directly contact the second semiconductor layer exposed by the first opening and the third opening. The second transparent electrode may directly contact the first semiconductor layer exposed by the second opening and the fourth opening.

The first semiconductor layer may include at least one n-type semiconductor layer, and the second semiconductor layer may include at least one p-type semiconductor layer.

The insulative film may cover an outer circumferential surface of a light emitting stack structure in which the first semiconductor layer and the second semiconductor layer are stacked.

In accordance with an aspect of the disclosure, a method of manufacturing a display device, the method may include manufacturing a pixel circuit layer disposed on a substrate; and manufacturing a display element layer disposed on the pixel circuit layer, wherein the manufacturing of the display element layer may include patterning an anode electrode and a cathode electrode on the pixel circuit layer; patterning a first reflective electrode electrically connected to the anode electrode and a second reflective electrode electrically connected to the cathode electrode; disposing, on the pixel circuit layer, a light emitting element including a first semiconductor layer, a second semiconductor layer, and an insulative film including a first opening and a second opening; and patterning a passivation layer on the first reflective electrode, the second reflective electrode, an inside of the second opening, and the light emitting element.

The second semiconductor layer may be exposed in the first opening, and the first semiconductor layer may be exposed in the second opening.

The passivation layer and the insulative film may directly contact each other in the second opening.

The method may include patterning, on the passivation layer, a first transparent electrode directly electrically connecting the second semiconductor layer to the first reflective electrode and a second transparent electrode directly electrically connecting the first semiconductor layer to the second reflective electrode.

The disposing of the light emitting element on the pixel circuit layer may include disposing the light emitting element on the pixel circuit layer in which the light emitting element is disposed on an upper substrate. The insulative film disposed at an upper portion of the light emitting element may directly contact the upper substrate.

The first semiconductor layer may include at least one n-type semiconductor layer, and the second semiconductor layer may include at least one p-type semiconductor layer.

The insulative film may cover an outer circumferential surface of a light emitting stack structure in which the first semiconductor layer and the second semiconductor layer are stacked.

In accordance with an aspect of the disclosure, an electronic device may include a display device including a display element layer disposed on a substrate, wherein the display element layer may include an anode electrode and a cathode electrode; a first reflective electrode disposed on the anode electrode; a second reflective electrode disposed on the cathode electrode; a light emitting element including a first semiconductor layer, a second semiconductor layer, and an insulative film; a first transparent electrode directly electrically connecting the second semiconductor layer to the first reflective electrode; and a second transparent electrode directly electrically connecting the first semiconductor layer to the second reflective electrode.

The electronic device may be at least one of a smart watch, a mobile phone, a smartphone, a portable computer, a tablet personal computer (PC), a watch phone, an automotive display, a smart glass, a portable multimedia player (PMP), a navigation system, an ultra mobile computer (UMPC), a head mounted display (HMD) device, a virtual reality (VR) device, a mixed reality (MR) device, and an augmented reality (AR) device.

### BRIEF DESCRIPTION OF THE DRAWINGS

The above and other aspects and features of the disclosure will become more apparent by describing in detail embodiments thereof with reference to the attached drawings, in which:

FIG. 1 is a block diagram illustrating an embodiment of a display device.

FIG. 2 is a block diagram illustrating an embodiment of any one of sub-pixels shown in FIG. 1.

FIG. 3 is a schematic plan view illustrating an embodiment of a display panel shown in FIG. 1.

FIG. 4 is a schematic sectional view illustrating an embodiment of the display panel shown in FIG. 3.

FIG. 5 is a schematic sectional view illustrating an embodiment of the display panel shown in FIG. 3.

FIG. 6 is a schematic plan view illustrating an embodiment of any one of pixels shown in FIG. 3.

FIG. 7 is a schematic sectional view illustrating an embodiment, which is taken along line A-A′ shown in FIG. 6.

FIG. 8 is a schematic flowchart illustrating a method of manufacturing a display device in accordance with an embodiment.

FIG. 9 is a schematic flowchart illustrating a step of manufacturing a display element layer in accordance with an embodiment.

FIGS. 10 to 16 are schematic sectional views illustrating process steps according to the step shown in FIG. 9.

FIG. 17 is a block diagram illustrating an embodiment of a display system.

FIGS. 18 to 21 are schematic perspective views illustrating application examples of the display system shown in FIG. 17.

### DETAILED DESCRIPTION OF THE EMBODIMENTS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

Hereinafter, embodiments will be described in more detail with reference to the accompanying drawings. In the drawing figures and dimensions may be exaggerated for clarity of illustration.

It will be understood that when an element is referred to as being “between” two elements, it can be the only element between the two elements, or one or more intervening elements may also be present. Like reference numerals refer to like elements throughout.

In the description below, a part for understanding an operation according to the disclosure is described and the descriptions of other parts may be omitted in order not to unnecessarily obscure subject matters of the disclosure. The disclosure is not limited to embodiments described herein, but may be embodied in various different forms. Rather, embodiments described herein are provided to thoroughly and completely describe the disclosed contents and to convey the disclosure to a person of ordinary skill in the art.

In the entire specification, when an element is referred to as being “connected” or “coupled” to another element, it can be directly connected or coupled to the another element or be indirectly connected or coupled to the another element with one or more intervening elements disposed therebetween.

The technical terms used herein are used only for the purpose of illustrating an embodiment and not intended to limit the embodiment. It will be understood that when a component “includes” an element, unless there is another opposite description thereto, it should be understood that the component does not exclude another element but may further include another element.

It will be understood that for the purposes of this disclosure, “at least one of X, Y, and Z” can be construed as X only, Y only, Z only, or any combination of two or more items X, Y, and Z (for example, XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (for example, XYZ, XYY, YZ, ZZ).

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the term, “above,” may encompass both an orientation of above and below. The apparatus may be otherwise oriented (for example, rotated 90 degrees or at other orientations) and the spatially relative descriptors used herein interpreted accordingly.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The embodiments of the disclosure are described here with reference to schematic diagrams of given embodiments (and an intermediate structure) of the disclosure, so that changes in a shape as shown due to, for example, manufacturing technology and/or a tolerance may be expected. Therefore, the embodiments of the disclosure shall not be limited to the shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments may be described and illustrated in the accompanying drawings in terms of functional blocks, units, and/or modules.

Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies.

In the case of the blocks, units, and/or modules being implemented by microprocessors or other similar hardware, they may be programmed and controlled using software (for example, microcode) to perform various functions discussed herein and may optionally be driven by firmware and/or software.

It is also contemplated that each block, unit, and/or module may be implemented by dedicated hardware, or as a combination of dedicated hardware to perform some functions and a processor (for example, one or more programmed microprocessors and associated circuitry) to perform other functions.

Each block, unit, and/or module of embodiments may be physically separated into two or more interacting and discrete blocks, units, and/or modules without departing from the scope of the disclosure.

Further, the blocks, units, and/or modules of embodiments may be physically combined into more complex blocks, units, and/or modules without departing from the scope of the disclosure.

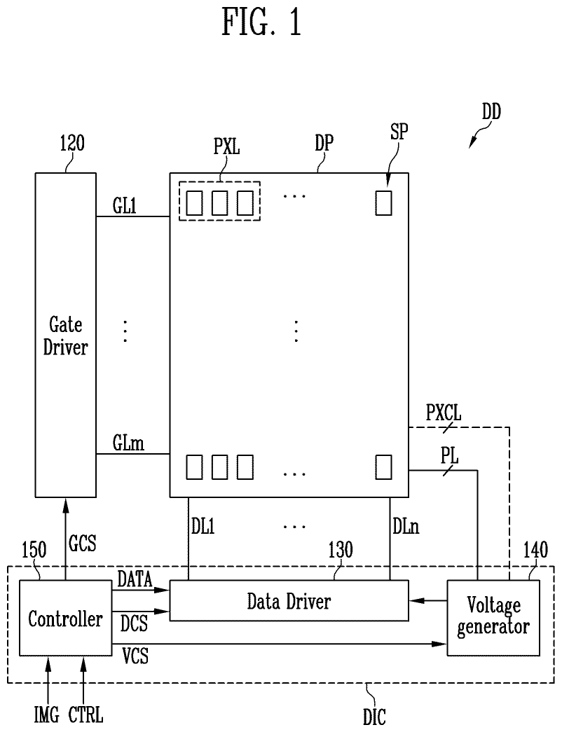

FIG. 1 is a block diagram illustrating an embodiment of a display device.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to mth gate lines GL1 to GLm. The sub-pixels SP may be connected to the data driver 130 through first to nth data lines DL1 to DLn.

The sub-pixels SP may generate lights of two or more colors. For example, each of the sub-pixels SP may generate lights of red, green, blue, cyan, magenta, yellow, white, and the like within the spirit and the scope of the disclosure.

Two or more sub-pixels among the sub-pixels SP may constitute a pixel PXL. For example, the pixel PXL may include three sub-pixels as shown in FIG. 1. As such, the pixel PXL may emit lights of various colors with various luminances according to a combination of lights emitted from the sub-pixels included therein.

The gate driver 120 may be connected to the sub-pixels SP arranged (or disposed) in a row direction through the first to mth gate lines GL1 to GLm. The gate driver 120 may output gate signals to the first to mth gate lines GL1 to GLm in response to a gate control signal GCS. In embodiments, the gate control signal GCS may include a start signal indicating a start of each frame, a horizontal synchronization signal, and the like within the spirit and the scope of the disclosure.

The gate driver 120 may be disposed at one side of the display panel DP. However, embodiments are not limited thereto. For example, the gate driver 120 may be divided into two or more drivers which are physically and/or logically divided, and these drivers may be disposed at one side of the display panel DP and the other side of the display panel DP, which is opposite to the one side. As such, in an embodiment, the gate driver 120 may be disposed in various forms at the periphery of the display panel DP.

The data driver 130 may be connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like within the spirit and the scope of the disclosure.

The data driver 130 may receive voltages from the voltage generator 140. The data driver 130 may apply data signals having grayscale voltages corresponding to the image data DATA to the first to nth data lines DL1 to DLn by using the received voltages. In case that a gate signal is applied to each of the first to mth gate lines GL1 to GLm, data signals corresponding to the image data DATA may be applied to the first to nth data line DL1 to DLm. Accordingly, corresponding sub-pixels SP may generate light corresponding to the data signals. Accordingly, an image may be displayed on the display panel DP.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate voltages and provide the generated voltages to components of the display device DD. The voltage generator 140 may generate voltages by receiving an input voltage from the outside of the display device DD and regulating the received voltage.

The voltage generator 140 may generate a first power voltage and a second power voltage. The generated first and second power voltages may be provided to the sub-pixels SP through power lines PL. In other embodiments, at least one of the first and second power voltages may be provided from the outside of the display device DD.

Besides, the voltage generator 140 may provide various voltages and/or signals. For example, the voltage generator 140 may provide one or more initialization voltages applied to the sub-pixels SP. For example, in a sensing operation for sensing electrical characteristics of transistors and/or light emitting elements of the sub-pixels SP, a selectable reference voltage may be applied to the first to nth data lines DL1 to DLn, and the voltage generator 140 may generate the reference voltage and transfer the reference voltage to the data driver 130. For example, in a display operation for displaying an image on the display panel DP, common pixel control signals may be applied to the sub-pixels SP, and the voltage generator 140 may generate the pixel control signals. In embodiments, the voltage generator 140 may provide the pixel control signals to the sub-pixels SP through pixel control lines PXCL. In FIG. 1, it is illustrated that the pixel control lines PXCL are connected between the voltage generator 140 and the display panel DP. However, embodiments are not limited thereto. For example, the pixel control lines PXCL may be connected between the gate driver 120 and the display panel DP. The pixel control signals may be transferred to the sub-pixels SP from the gate driver 120 through the pixel control lines PXCL.

The controller 150 may control overall operations of the display device DD. The controller 150 may receive, from the outside, input image data IMG and a control signal CTRL corresponding thereto. The controller 150 may provide the gate control signal GCS, the data control signal DCS, and the voltage control signal VCS in response to the control signal CTRL.

The controller 150 may convert the input image data IMG to be suitable for the display device DD or the display panel DP, thereby outputting the image data DATA. In embodiments, the controller 150 may align the input image data IMG to be suitable for the sub-pixels SP in units of rows, thereby outputting the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. In other embodiments, at least one of the data driver 130, the voltage generator 140, and the controller 150 may be provided as a component distinguished from the driver integrated circuit DIC.

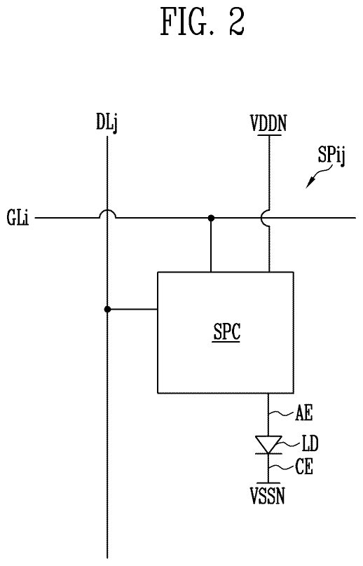

FIG. 2 is a block diagram illustrating an embodiment of any one of the sub-pixels shown in FIG. 1. In FIG. 2, a sub-pixel SPij arranged on an ith row (i is an integer greater than or equal to 1 and smaller than or equal to m) and a jth column (j is an integer greater than or equal to 1 and smaller than or equal to n) among the sub-pixels SP shown in FIG. 1 is illustrated.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be connected to one of the power lines PL shown in FIG. 1, to receive a first power voltage. The second power voltage node VSSN may be connected to another of the power lines PL, to receive a second power voltage. The first power voltage may have a voltage level higher than a voltage level of the second power voltage.

The light emitting element LD may be connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD may be configured to emit light according to a current flowing from the anode electrode AE to the cathode electrode CE.

The sub-pixel circuit SPC may be connected to an ith gate line GLi among the first to mth gate lines GL1 to GLm shown in FIG. 1 and a jth data line DLj among the first to nth data lines DL1 to DLn shown in FIG. 1. In response to a gate signal received through the ith gate line GLi, the sub-pixel circuit SPC may control the light emitting element LD to emit light according to a data signal received through the jth data line DLj. In embodiments, the sub-pixel circuit SPC may be further connected to the pixel control lines PXCL shown in FIG. 1. The sub-pixel circuit SPC may control the light emitting element LD in further response to control signals received through the pixel control lines PXCL.

For these operations, the sub-pixel circuit SPC may include circuit elements, for example, transistors and one or more capacitors.

The transistors of the sub-pixel circuit SPC may include P-type transistors and/or N-type transistors. In embodiments, the transistors of the sub-pixel circuit SPC may include a Metal Oxide Silicon Field Effect Transistor (MOSFET). In embodiments, the transistors of the sub-pixel circuit SPC may include an amorphous silicon semiconductor, a monocrystalline silicon semiconductor, polycrystalline silicon semiconductor, an oxide semiconductor, and the like within the spirit and the scope of the disclosure.

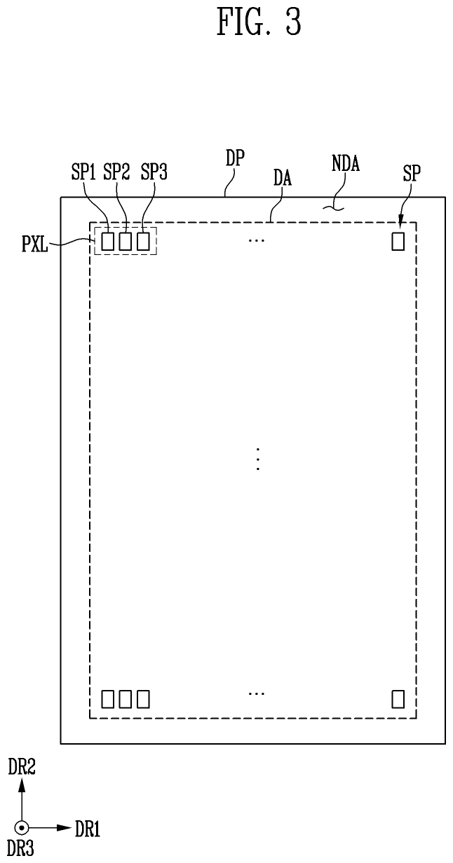

FIG. 3 is a schematic plan view illustrating an embodiment of the display panel shown in FIG. 1.

Referring to FIG. 3, a display panel DP may include a display area DA and a non-display area NDA. The display panel DP displays an image through the display area DA. The non-display area NDA may be disposed at the periphery of the display area DA.

The display panel DP may include sub-pixels SP in the display area DA. The sub-pixels SP may be arranged in a first direction DR1 and a second direction DR2 intersecting the first direction DR1. For example, the sub-pixels SP may be arranged in a matrix form along the first direction DR1 and the second direction DR2. In another example, the sub-pixels SP may be arranged in a zigzag form along the first direction DR1 and the second direction DR2. The arrangement of the sub-pixels SP may vary in an embodiment. The first direction DR1 may be a row direction, and the second direction DR2 may be a column direction.

Two or more sub-pixels among the sub-pixels SP may constitute one pixel PXL. In FIG. 3, it is illustrated that the pixel PXL may include three sub-pixels SP1 to SP3. However, embodiments are not limited thereto. For example, the pixel PXL may include two sub-pixels. Hereinafter, for convenience of description, it is assumed that the pixel PXL may include first to third sub-pixels SP1 to SP3.

Each of the first to third sub-pixels SP1 to SP3 may generate light of one of various colors such as red, green, blue, cyan, magenta, and yellow. Hereinafter, for clear and simple description, it is assumed that the first sub-pixel SP1 is configured to generate light of a red color, the second sub-pixel SP2 is configured to generate light of a green color, and the third sub-pixel SP3 is configured to generate light of a blue color.

Each of the first to third sub-pixels SP1 to SP3 may include at least one light emitting element configured to generate light. In embodiments, light emitting elements of the first to third sub-pixels SP1 to SP3 may generate light of the same color. For example, the light emitting elements of the first to third sub-pixels SP1 to SP3 may generate light of a blue color. In other embodiments, the light emitting elements of the first to third sub-pixels SP1 to SP3 may generate lights of different colors. For example, the light emitting elements of the first to third sub-pixels SP1 to SP3 may generate lights a red color, a green color, and a blue color, respectively.

Self-luminous display panels, such as a light emitting diode display panel (LED display panel) using a light emitting diode of micro scale or nano scale as a light emitting element and an organic light emitting display panel (OLED panel) using an organic light emitting diode as a light emitting element, may be used as the display panel DP.

A component for controlling the sub-pixels SP may be disposed in the non-display area NDA. Lines connected to the sub-pixels SP, for example, the first to mth gate lines GL1 to GLm, the first to nth data lines DL1 to DLn, the power lines PL, and the pixel control lines PXCL, which are shown in FIG. 1, may be disposed in the non-display area NDA.

At least one of the gate driver 120, the data driver 130, the voltage generator 140, and the controller 150, which are shown in FIG. 1, may be disposed in the non-display area NDA of the display panel DP. In embodiments, the gate driver 120 may be disposed in the non-display area NDA. The data driver 130, the voltage generator 140, and the controller 150 may be implemented into the driver integrated circuit DIC shown in FIG. 1, which is distinguished from the display panel DP, and the driver integrated circuit DIC may be connected to the lines disposed in the non-display area NDA. In other embodiments, the gate driver 120, the data driver 130, the voltage generator 140, and the controller 150 may be implemented into one integrated circuit distinguished from the display panel DP.

In embodiments, the display area DA may have various shapes. The display area DA may have a closed-loop shape including linear sides and/or curved sides. For example, the display area DA may have shapes such as a polygon, a circle, a semicircle, and an ellipse.

In embodiments, the display panel DP may have a flat display surface. In other embodiments, the display panel DP may at least partially have a round display surface. In embodiments, the display panel DP may be bendable, foldable or rollable. The display panel DP and/or a substrate of the display panel DP may include materials having flexibility.

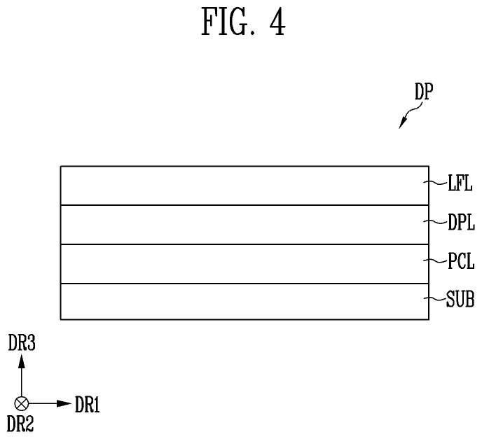

FIG. 4 is a schematic sectional view illustrating an embodiment of the display panel shown in FIG. 3.

Referring to FIG. 4, a display panel DP may include a substrate SUB, and a pixel circuit layer PCL, a display element layer DPL, and a light functional layer LFL, which may be sequentially stacked in a third direction DR3 intersecting the first and second directions DR1 and DR2 on the substrate SUB.

The substrate SUB may be made of an insulative material such as glass or resin. For example, the substrate SUB may include a glass substrate. In another example, the substrate SUB may include polyimide (PI) substrate. In another example, the substrate SUB may include a silicon wafer substrate formed using a semiconductor process.

In embodiments, the substrate SUB may be made of a material having flexibility to be curvable or foldable, and have a single-layer structure or a multi-layer structure. For example, the material having flexibility may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers, and semiconductor patterns and conductive patterns, which are disposed between the insulating layers. The conductive patterns of the pixel circuit layer PCL may serve as circuit elements, lines, and the like within the spirit and the scope of the disclosure.

The circuit elements of the pixel circuit layer PCL may constitute a sub-pixel circuit SPC of each of the sub-pixels SP shown in FIG. 3. In other words, the circuit elements of the pixel circuit layer PCL may be provided as transistors and one or more capacitors of the sub-pixel circuit SPC.

The lines of the pixel circuit layer PCL may include lines connected to each of the sub-pixels SP. The lines of the pixel circuit layer PCL may include various signal lines and/or various voltage lines, which are desirable for driving the display element layer DPL.

The display element layer DPL may be disposed on the pixel circuit layer PCL. The display element layer DPL may include light emitting elements of the sub-pixels SP.

The light functional layer LFL may be disposed on the display element layer DPL. The light functional layer LFL may include light conversion patterns having color conversion particles and/or light scattering particles. For example, color conversion particles may include quantum dots. The quantum dots may change a wavelength (or color) of light emitted from the display element layer DPL. The light functional layer LFL may further include light scattering patterns having light scattering particles. In embodiments, the light conversion patterns and the light scattering patterns may be omitted.

The light functional layer LFL may further include a color filter layer including color filters. The color filter may allow light having a given wavelength (or a given color) to be selectively transmitted therethrough. In embodiments, the color filter layer may be omitted.

A window for protecting an exposed surface (or top surface) of the display panel DP may be provided on the light functional layer LFL. The window may protect the display panel DP from external impact. The window may be bonded to the light functional layer LFL through an optically transparent adhesive (or cohesive) member. The window may have a multi-layer structure selected from a glass substrate, a plastic film, and a plastic substrate. This multi-layer structure may be formed through a continuous process or an adhesive process using an adhesive layer. The whole or a portion of the window may have flexibility.

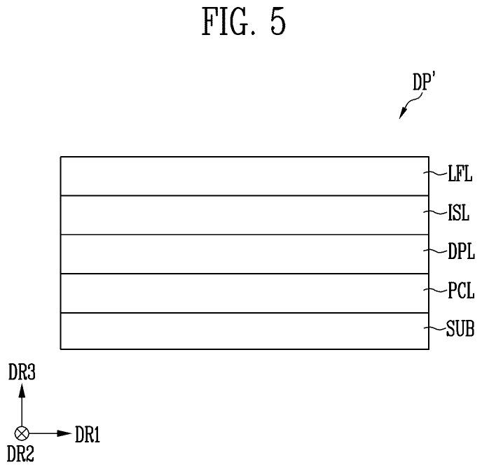

FIG. 5 is a schematic sectional view illustrating an embodiment of the display panel shown in FIG. 3.

Referring to FIG. 5, a display panel DP′ may include a substrate SUB, a pixel circuit layer PCL, a display element layer DPL, an input sensing layer ISL, and a light functional layer LFL. The substrate SUB, the pixel circuit layer PCL, the display element layer DPL, and the light functional layer LFL may be configured identically to the substrate SUB, the pixel circuit layer PCL, the display element layer DPL, and the light functional layer LFL, which are described with reference to FIG. 4, respectively. Hereinafter, overlapping descriptions may be omitted.

The input sensing layer ISL may sense a user input with respect to a top surface (or display surface) of the display panel DP′. The input sensing layer ISL may include components suitable for sensing an external object such as a hand of a user or a pen. For example, the input sensing layer ISL may include touch electrodes.

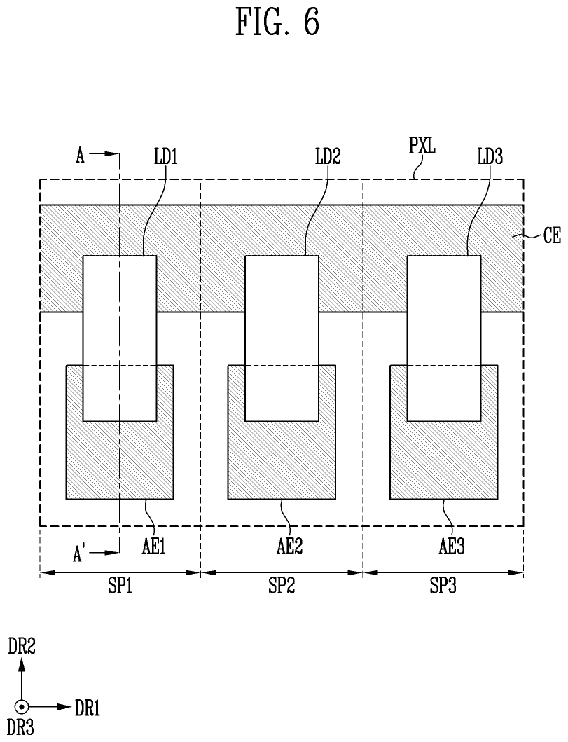

FIG. 6 is a schematic plan view illustrating an embodiment of any one of the pixels shown in FIG. 3.

Referring to FIG. 6, a pixel PXL may include first to third sub-pixels SP1 to SP3. The first to third sub-pixels SP1 to SP3 may be arranged in the first direction DR1. However, the arrangement of the pixel PXL is not limited thereto, and may be variously changed in an embodiment. For example, the first to third sub-pixels SP1 to SP3 may be arranged in a zigzag form or a zigzag pattern.

First to third anode electrodes AE1 to AE3 may be disposed in the first to third sub-pixels SP1 to SP3, respectively. The first anode electrode AE1 may be provided as an anode electrode AE (see FIG. 2) connected to a sub-pixel circuit SPC (see FIG. 2) of the first sub-pixel SP1. The second anode electrode AE2 may be provided as an anode electrode AE connected to a sub-pixel circuit SPC of the second sub-pixel SP2. The third anode electrode AE3 may be provided as an anode electrode AE connected to a sub-pixel circuit SPC of the third sub-pixel SP3.

A cathode electrode CE may be spaced apart from the first to third anode electrodes AE1 to AE3. The cathode electrode CE may be disposed at the same height as the first to third anode electrodes AE1 to AE3. The cathode electrode CE may be spaced apart from the first to third anode electrodes AE1 to AE3 in the second direction DR2. In embodiments, the cathode electrode CE may extend in the first direction DR1, to be used as a common electrode of the pixel PXL and other pixels adjacent to the pixel PXL. Although not shown in the drawing, the cathode electrode CE may extend in the second direction DR2 in addition to the first direction DR1, to be used as a common electrode of all the sub-pixels SP shown in FIG. 3. As such, the cathode electrode CE may have various shapes. In embodiments, the first to third anode electrodes AE1 to AE3 and the cathode electrode CE may include the same conductive material.

First to third light emitting elements LD1 to LD3 may be disposed on the first to third anode electrodes AE1 to AE3 and the cathode electrode CE. The first light emitting element LD1 may be electrically connected to the first anode electrode AE1 and the cathode electrode CE. The first light emitting element LD1 may be provided as a light emitting element LD (see FIG. 2) connected to the sub-pixel circuit SPC of the first sub-pixel SP1. The second light emitting element LD2 may be electrically connected to the second anode electrode AE2 and the cathode electrode CE. The second light emitting element LD2 may be provided as a light emitting element LD connected to the sub-pixel circuit SPC of the second sub-pixel SP2. The third light emitting element LD3 may be electrically connected to the third anode electrode AE3 and the cathode electrode CE. The third light emitting element LD3 may be provided as a light emitting element LD connected to the sub-pixel circuit SPC of the third sub-pixel SP3.

The first light emitting element LD1, the second light emitting element LD2, and the third light emitting element LD3 may be inorganic light emitting diodes including an inorganic light emitting material. However, embodiments are not limited thereto. For example, organic light emitting diodes may be used.

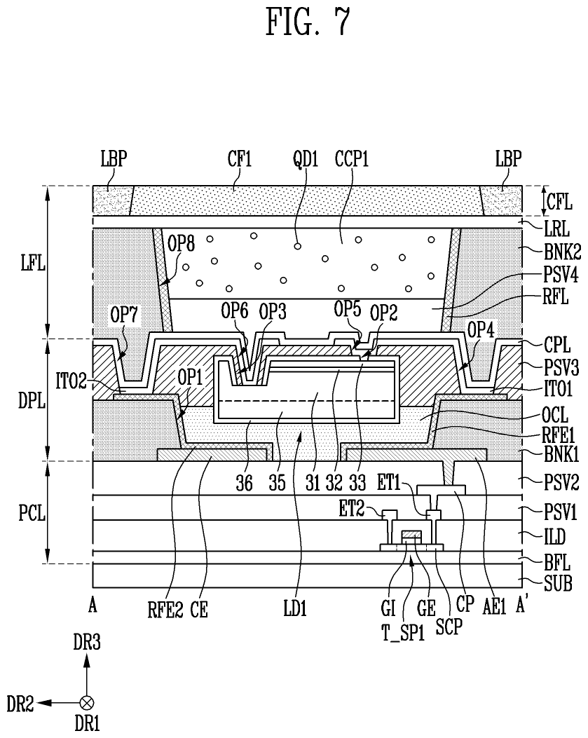

FIG. 7 is a schematic sectional view illustrating an embodiment of the disclosure, which is taken along line A-A′ shown in FIG. 6.

Referring to FIGS. 6 and 7, a pixel circuit layer PCL, a display element layer DPL, and a light functional layer LFL may be sequentially disposed on a substrate SUB.

Sub-pixel circuits respectively corresponding to the first to third sub-pixels SP1 to SP3 may be provided in the pixel circuit layer PCL.

The pixel circuit layer PCL may include insulating layers, semiconductor patterns, and conductive patterns, which are stacked on the substrate SUB. The insulating layers may include a buffer layer BFL, one or more interlayer insulating layers ILD, and one or more passivation layers PSV1 and PSV2. The semiconductor patterns and the conductive patterns may be located (or disposed) between the insulating layers. The conductive patterns may include at least one material among copper (Cu), molybdenum (Mo), tungsten (W), aluminum neodymium (AlNd), titanium (Ti), aluminum (Al), and silver (Ag).

As described with reference to FIG. 2, the sub-pixel circuit SPC (see FIG. 2) of each of the first to third sub-pixels SP1, SP2, and SP3 may include transistors and capacitors. The semiconductor patterns and the conductive patterns of the pixel circuit layer PCL may serve as the transistors and the capacitors of the sub-pixel circuit SPC. The conductive patterns of the pixel circuit layer PCL may further serve as lines, for example, the first to mth gate lines GL1 to GLm, the first to nth data lines DL1 to DLn, the power lines PL, and the pixel control lines PXCL, which are shown in FIG. 1.

The buffer layer BFL may be disposed on one surface of the substrate SUB. The buffer layer BFL may prevent an impurity from being diffused into circuit elements and lines, which are included in the pixel circuit layer PCL. The buffer layer BFL may include an inorganic insulating layer including an inorganic material. In embodiments, the buffer layer BFL may include at least one of silicon nitride (SiNₓ), silicon oxide (SiOₓ), silicon oxynitride (SiOₓN_{y}), and a metal oxide such as aluminum oxide (AlOₓ). The buffer layer BFL may be provided as a single layer or a multi-layer. In case that the buffer layer BFL is provided as the multi-layer, layers of the multi-layer may be formed of a same material or be formed of different materials.

In embodiments, one or more barrier layers may be disposed between the substrate SUB and the buffer layer BFL. Each of the barrier layers may include polyimide.

A transistor T_SP1 may be disposed on the buffer layer BFL. The transistor T_SP1 may be any one of the transistors of the sub-pixel circuit SPC included in the first sub-pixel SP1. For example, the transistor T_SP1 may be understood as a transistor connected to the first anode electrode AE1 among the transistors of the sub-pixel circuit SPC.

The transistor T_SP1 may include a semiconductor pattern SCP, a gate electrode GE, a first terminal ET1, and a second terminal ET2. The first terminal ET1 may be any one of a source electrode and a drain electrode, and the second terminal ET2 may be the other of the source electrode and the drain electrode. For example, the first terminal ET1 may be the source electrode, and the second terminal ET2 may be the drain electrode.

The semiconductor pattern SCP may be disposed on the buffer layer BFL. The semiconductor pattern SCP may include a first contact region in contact with the first terminal ET1 and a second contact region in contact with the second terminal ET2. A region between the first contact region and the second contact region may be a channel region. The channel region may overlap the gate electrode GE of the transistor T_SP1. The channel region is a semiconductor pattern undoped with an impurity, and may be an intrinsic semiconductor. Each of the first contact region and the second contact region may be a semiconductor pattern doped with the impurity. For example, a p-type impurity may be used as the impurity, but embodiments are not limited thereto.

The semiconductor pattern SCP may include any one of various types of semiconductors, for example, any one of an amorphous silicon semiconductor, a monocrystalline silicon semiconductor, a polycrystalline silicon semiconductor, a low temperature poly-silicon semiconductor, and an oxide semiconductor.

The sequentially stacked interlayer insulating layers ILD may be disposed over the semiconductor pattern SCP. The interlayer insulating layers ILD may be inorganic insulating layers including an inorganic material. For example, each of the interlayer insulating layers ILD may include at least one of silicon nitride (SiNₓ), silicon oxide (SiOₓ), silicon oxynitride (SiOₓN_{y}), and a metal oxide such as aluminum oxide (AlOₓ). However, the interlayer insulating layers ILD are not limited thereto. For example, any one of the interlayer insulating layers ILD may include an organic insulating layer including an organic material.

The interlayer insulating layers ILD may electrically separate the conductive patterns and/or the semiconductor patterns, which are disposed between the interlayer insulating layers ILD. For example, the interlayer insulating layers ILD may include a gate insulating layer GI disposed on the semiconductor pattern SCP. The gate insulating layer GI may be disposed between the semiconductor pattern SCP and the gate electrode GE such that the gate electrode GE is spaced apart from the semiconductor pattern SCP. In embodiments, the gate insulating layer GI may be entirely provided on the semiconductor pattern SCP and the buffer layer BFL, to cover the semiconductor pattern SCP and the buffer layer BFL. As the number of layers required to form the conductive patterns and/or the semiconductor patterns increases, the number of interlayer insulating layers ILD may increase.

The gate electrode GE may be disposed on the gate insulating layer GI. The gate electrode GE may overlap the channel region of the semiconductor pattern SCP. The gate electrode GE may be provided as a single layer including at least one material among copper (Cu), molybdenum (Mo), tungsten (W), aluminum neodymium (AlNd), titanium (Ti), aluminum (Al), and silver (Ag). In embodiments, the gate electrode GE may be provided as a multi-layer including at least one material among molybdenum (Mo), titanium (Ti), copper (Cu), aluminum (Al), and silver (Ag), which are low resistance materials.

The first and second terminals ET1 and ET2 may be disposed on the interlayer insulating layers ILD. The first and second terminals ET1 and ET2 may be in contact with the semiconductor pattern SCP through contact holes penetrating the interlayer insulating layers ILD. The first and second terminals ET1 and ET2 may be in contact with the first and second contact regions of the semiconductor pattern SCP, respectively. Each of the first and second terminals ET1 and ET2 may include at least one material among copper (Cu), molybdenum (Mo), tungsten (W), aluminum neodymium (AlNd), titanium (Ti), aluminum (Al), and silver (Ag).

Although the first and second terminals ET1 and ET2 are illustrated as individual electrodes electrically connected to the semiconductor pattern SCP, embodiments are not limited thereto. In embodiments, the first terminal ET1 may be the first contact region adjacent to one side of the channel region of the semiconductor pattern SCP, and the second terminal ET2 may be the second contact region adjacent to the other side of the channel region of the semiconductor pattern SCP. The first terminal ET1 may be electrically connected to a light emitting element LD through a connection means such as a bridge electrode, which is disposed on at least one of the interlayer insulating layers ILD.

In embodiments, the transistor T_SP1 may be configured as a low temperature poly-silicon transistor. However, embodiments are not limited thereto. For example, the transistor T_SP1 may be configured as an oxide semiconductor transistor. In embodiments, the sub-pixel circuit of the first sub-pixel SP1 may include different types of transistors. For example, the transistor T_SP1 may be configured as a low temperature poly-silicon transistor, and another transistor of the first sub-pixel SP1 may be configured as an oxide semiconductor transistor. An oxide semiconductor of the corresponding oxide semiconductor transistor may be disposed on any one of the interlayer insulating layers ILD instead of an insulating layer on which the semiconductor pattern SCP of the transistor T_SP1 is disposed.

In embodiments, a case where the transistor T_SP1 is a transistor having a top gate structure is described as an example. However, embodiments are not limited thereto. For example, the transistor T_SP1 may be a transistor having a bottom gate structure. The structure of the transistor T_SP1 may be variously changed.

At least some of various lines of the display panel DP and/or the display device DD may be further disposed on the interlayer insulating layers ILD.

A first passivation layer PSV1 may be disposed over the interlayer insulating layers ILD and the first and second terminals ET1 and ET2. A passivation layer may be designated as a protective layer or a via layer. The first passivation layer PSV1 may protect components disposed thereunder, and provide a flat top surface.

A connection pattern CP may be disposed on the first passivation layer PSV1. The connection pattern CP may be connected to the first terminal ET1 of the transistor T_SP1 while penetrating the first passivation layer PSV1. The connection pattern CP may include at least one material among copper (Cu), molybdenum (Mo), tungsten (W), aluminum neodymium (AlNd), titanium (Ti), aluminum (Al), and silver (Ag).

At least some of various lines of the display panel DP and/or the display device DD may be further disposed on the first passivation layer PSV1.

A second passivation layer PSV2 may be disposed over the connection pattern CP and the first passivation layer PSV1. The second passivation layer PSV2 may protect components disposed thereunder, and provide a flat top surface.

Each of the first and second passivation layers PSV1 and PSV2 may include an inorganic insulating layer including an inorganic material and/or an organic insulating layer including an organic material. The inorganic insulating layer may include, for example, at least one of silicon oxide (SiOₓ), silicon nitride (SiNₓ), silicon oxynitride (SiOₓN_{y}), and a metal oxide such as aluminum oxide (AlOₓ). The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin.

The first and second passivation layers PSV1 and PSV2 may include a same material as any one of the interlayer insulating layers ILD, but embodiments are not limited thereto. Each of the first and second passivation layers PSV1 and PSV2 may be provided as a single layer, but be provided as a multi-layer.

The display element layer DPL may be disposed on the second passivation layer PSV2. The display element layer DPL may include a first anode electrode AE1, a cathode electrode CE, a first bank BNK1, first and second reflective electrodes RFE1 and RFE2, an overcoat layer OCL, a first light emitting element LD1, a third passivation layer PSV3, first and second transparent electrodes ITO1 and ITO2, and a capping layer CPL.

The first anode electrode AE1 and the cathode electrode CE may be disposed on the pixel circuit layer PCL.

The first anode electrode AE1 may be electrically connected to the connection pattern CP through a contact hole penetrating the second passivation layer PSV2. As such, the first anode electrode AE1 may be electrically connected to the transistor T_SP1.

The cathode electrode CE may be spaced apart from the first anode electrode AE1 in the second direction DR2. The cathode electrode CE may be electrically connected to the second power voltage node VSSN shown in FIG. 2. Accordingly, the second power voltage applied to the second power voltage node VSSN may be transferred to the cathode electrode CE.

The first bank BNK1 may be disposed on the first anode electrode AE1 and the cathode electrode CE. The first bank BNK1 may have a first opening OP1 exposing portions of the first anode electrode AE1 and the cathode electrode CE. The first light emitting element LD1 may be disposed in the first opening OP1 of the first bank BNK1. As such, the first bank BNK1 may be provided as a pixel defining layer defining an area in which the first light emitting element LD1 is located.

The first bank BNK1 may be configured to include a light blocking material, to prevent light mixture between adjacent sub-pixels. In embodiments, the first bank BNK1 may include an organic material. For example, the first bank BNK1 may include an organic insulating material such as acrylic resin, epoxy resin, phenolic resin, polyamide resin, or polyimide resin.

In accordance with embodiments, the first bank BNK1 may be omitted, or be disposed in another form.

The first reflective electrode RFE1 may be disposed on an exposed portion of the first anode electrode AE1 and a side surface of the first bank BNK1, which is adjacent thereto. The second reflective electrode RFE2 may be disposed on an exposed portion of the cathode electrode CE and a side surface of the first bank BNK1, which is adjacent thereto. The first and second reflective electrodes RFE1 and RFE2 may include conductive materials suitable for reflecting light. Accordingly, the light output efficiency of the first light emitting element LD1 can be improved. In embodiments, the first and second reflective electrodes RFE1 and RFE2 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

On the first and second reflective electrodes RFE1 and RFE2 and the second passivation layer PSV2, the overcoat layer OCL may be disposed in the first opening OP1 of the first bank BNK1. The first light emitting element LD1 on the overcoat layer OCL. The first light emitting element LD1 may be partially buried in the overcoat layer OCL.

The overcoat layer OCL may fix the first light emitting element LD1 not to move. Also, the overcoat layer OCL may protect components disposed thereunder from a foreign matter such as dust or moisture. For example, the overcoat layer OCL may include at least one of an inorganic insulating layer and an organic insulating layer. For example, the overcoat layer OCL may include epoxy, but embodiments are not limited thereto.

The first light emitting element LD1 may include a first semiconductor layer, an active layer 32, a second semiconductor layer 33, and an auxiliary layer 35. The first light emitting element LD1 may include a light emitting stack structure in which the auxiliary layer 35, the first semiconductor layer 31, the active layer 32, and the second semiconductor layer 33 may be sequentially stacked.

The first semiconductor layer 31 is configured to provide electrons to the active layer 32. The first semiconductor layer 31 may include, for example, at least one n-type semiconductor layer. For example, the first semiconductor layer 31 may include any one semiconductor material among gallium nitride (GaN), aluminum gallium nitride (AlGaN), indium gallium nitride (InGaN), aluminum nitride (AlN), and indium nitride (InN), and be an n-type semiconductor layer doped with a first conductive dopant (or n-type dopant) such as silicon (Si), germanium (Ge) or tin (Sn). However, the material constituting the first semiconductor layer 31 is not limited thereto. Various materials may constitute the first semiconductor layer 31. In an embodiment of the disclosure, the first semiconductor layer 31 may include a gallium nitride (GaN) semiconductor material doped with the first conductive dopant (or n-type dopant). In an embodiment, the first semiconductor layer 31 along with the auxiliary layer 35 may constitute an n-type semiconductor layer.

The active layer 32 may be disposed on the first semiconductor layer 31, and may be an area in which electrons and holes are recombined. As electrons and holes are recombined in the active layer 32, light may be generated, which has a level changed to a low energy level and has a wavelength corresponding to the low energy level. The active layer 32 may be formed in a single quantum well structure or a multi-quantum well structure. In case that the active layer 32 is formed in the multi-quantum well structure, a unit including a barrier layer, a strain reinforcing layer, and a well layer may be repeatedly stacked, to form the active layer 32. However, embodiments of the active layer 32 are not limited thereto.

The second semiconductor layer 33 may be disposed on the active layer 32, and provides holes to the active layer 32. The second semiconductor layer 33 may include a semiconductor layer of which type is different from the type of the first semiconductor layer 31. In an example, the second semiconductor layer 33 may include at least one p-type semiconductor layer. For example, the second semiconductor layer 33 may include any one semiconductor material among gallium nitride (GaN), aluminum gallium nitride (AlGaN), indium gallium nitride (InGaN), aluminum nitride (AlN), and indium nitride (InN), and be a p-type semiconductor layer doped with a second conductive dopant (or p-type dopant) such as magnesium (Mg), zinc (Zn), calcium (Ca), strontium (Sr) or barium (Ba). However, the material constituting the second semiconductor layer 33 is not limited thereto. Various materials may constitute the second semiconductor layer 33. In an embodiment of the disclosure, the second semiconductor layer 33 may include a gallium nitride (GaN) semiconductor material doped with the second conductive dopant (or p-type dopant).

The auxiliary layer 35 may include a gallium nitride (GaN) semiconductor material undoped with an impurity. The auxiliary layer 35 along with the first semiconductor layer 31 may constitute an n-type semiconductor layer.

The first light emitting element LD1 may further include an insulative film 36 covering an outer circumferential surface of the light emitting stack structure. The insulative film 36 may prevent an electrical short circuit which may occur while the active layer 32 is in contact with another conductive material except the first and second semiconductor layers 31 and 33. The insulative film 36 may include a transparent insulating material.

The insulative film 36 may be etched such that the second semiconductor layer 33 is exposed in a second opening OP2. The insulative film 36, the second semiconductor layer 33, and the active layer 32 may be etched such that the first semiconductor layer 31 is exposed in a third opening OP3.

The second opening OP2 and the third opening OP3 may be disposed to face in the same direction. For example, the second opening OP2 and the third opening OP3 may face in the third direction DR3. Also, the second opening OP2 and the third opening OP3 may be disposed at a top surface of the first light emitting element LD1.

The third passivation layer PSV3 may be disposed on the first and second reflective electrodes RFE1 and RFE2, the first light emitting element LD1, and the overcoat layer OCL. Also, the third passivation layer PSV3 may be disposed on the insulative film 36 adjacent to the third opening OP3. In the third opening OP3, a separate electrode or line is not disposed between the third passivation layer PSV3 and the insulative film 36, but the insulative film 36 and the third passivation layer PSV3 may be in contact with each other.

Although cracks are generated in the third opening OP3 in a transferring process of the first light emitting element LD1 or a bonding process of the first light emitting element LD1, the third passivation layer PSV3 can prevent a leakage current caused by the cracks. Accordingly, a defect (for example, a dark spot defect) of the display device DD, which is caused by the leakage current, can be decreased.

The third passivation layer PSV3 may protect components disposed thereunder, and provide a flat top surface. The third passivation layer PSV3 may have a same material as any one of the first and second passivation layers PSV1 and PSV2, but embodiments are not limited thereto.

The third passivation layer PSV3 may have fourth to seventh openings OP4 to OP7. The fourth opening OP4 may expose a portion of the first reflective electrode RFE1. The fifth opening OP5 may expose a portion of the top surface of the first light emitting element LD1. The fifth opening OP5 may overlap the second opening OP2 of the first light emitting element LD1. The second semiconductor layer 33 may be exposed in an area in which the second opening OP2 and the fifth opening OP5 overlap each other.

In FIG. 7, it is illustrated that the fifth opening OP5 is larger than the second opening OP2. However, the disclosure is not limited thereto, and the second opening OP2 and the fifth opening OP5 may expose the same area.

The sixth opening OP6 may expose a portion of the top surface of the first light emitting element LD1. The sixth opening OP6 may be formed inside the third opening OP3. For example, the third passivation layer PSV3 disposed inside the third opening OP3 may include the sixth opening OP6.

The sixth opening OP6 may overlap the third opening OP3 of the first light emitting element LD1. The first semiconductor layer 31 may be exposed in an area in which the third opening OP3 and the sixth opening OP6 overlap each other. The seventh opening OP7 may expose a portion of the second reflective electrode RFE2.

The first and second transparent electrodes ITO1 and ITO2 may be disposed on the third passivation layer PSV3. The first transparent electrode ITO1 may electrically connect the first reflective electrode RFE1 exposed by the fourth opening OP4 to the portion of the top surface of the first light emitting element LD1, which is exposed by the fifth opening OP5.

By way of example, the first transparent electrode ITO1 may electrically connect the first reflective electrode RFE1 exposed by the second opening OP2 to the second semiconductor layer 33 exposed by the second opening OP2 and the fifth opening OP5. For example, the first transparent electrode ITO1 may be directly connected to the second semiconductor layer 33 exposed by the second opening OP2 and the fifth opening OP5.

The second transparent electrode ITO2 may electrically connect the second reflective electrode RFE2 exposed by the seventh opening OP7 to the portion of the top surface of the first light emitting element LD1, which is exposed by the sixth opening OP6.

By way of example, the second transparent electrode ITO2 may electrically connect the second reflective electrode RFE2 exposed by the seventh opening OP7 to the first semiconductor layer 31 exposed by the third opening OP3 and the sixth opening OP6. For example, the second transparent electrode ITO2 may be directly connected to the first semiconductor layer 31 exposed by the third opening OP3 and the sixth opening OP6.

Accordingly, the second semiconductor layer 33 may be electrically connected to the first anode electrode AE1 through the first transparent electrode ITO1 and the first reflective electrode RFE1. The first semiconductor layer 31 may be electrically connected to the cathode electrode CE through the second transparent electrode ITO2 and the second reflective electrode RFE2.

In embodiments, the first and second transparent electrodes ITO1 and ITO2 may be formed substantially transparent or translucent to satisfy a selectable light transmittance. In embodiments, the first and second transparent electrodes ITO1 and ITO2 may include at least one of various transparent conductive materials such as indium tin oxide (ITO), indium zinc oxide (IZO), zinc oxide (ZnO), indium gallium zinc oxide (IGZO), and indium tin zinc oxide (ITZO). However, the material of the first and second transparent electrodes ITO1 and ITO2 is not limited thereto.

The capping layer CPL may be disposed on the third passivation layer PSV3. The capping layer CPL may protect components disposed under or below the capping layer CPL, such as the first and second transparent electrodes ITO1 and ITO2 and the first light emitting element LD1, from external moisture, humidity, and the like within the spirit and the scope of the disclosure. The capping layer CPL may include at least one of silicon nitride (SiNₓ), silicon oxide (SiOₓ), silicon oxynitride (SiOₓN_{y}), and a metal oxide such as aluminum oxide (AlOₓ). However, the material of the capping layer CPL is not limited thereto.

In the above, the pixel circuit layer PCL and the display element layer DPL of the first sub-pixel SP1 have been described. Each of the second and third sub-pixels SP2 and SP3 shown in FIG. 6 may also be configured identically to the first sub-pixel SP1 in a range in which it is not differently described herein.

The light functional layer LFL may be disposed on the capping layer CPL. The light functional layer LFL may include the second bank BNK2, the reflective layer RFL, a fourth passivation layer PSV4, a first light conversion pattern CCP1, a low refractive layer LRL, and a color filter layer CFL.

The second bank BNK2 may be disposed on the capping layer CPL. The second bank BNK2 may overlap the first bank BNK1. The second bank BNK2 may have an eighth opening OP8 overlapping the first opening OP1.

The second bank BNK2 may be configured to include a light blocking material, to prevent light mixture between adjacent sub-pixels. In embodiments, the second bank BNK2 may include an organic material. For example, the second bank BNK2 may include an organic insulating material such as acrylic resin, epoxy resin, phenolic resin, polyamide resin, or polyimide resin.

The reflective layer RFL may be disposed on side surfaces of the second bank BNK2, which are adjacent to the eighth opening OP8. The reflective layer RFL is configured to reflect incident light, and accordingly, light output efficiency can be improved. The reflective layer RFL may include a material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

On the capping layer CPL, the fourth passivation layer PSV4 may be disposed in the eighth opening OP8. The fourth passivation layer PSV4 may protect components disposed thereunder, and provide a flat surface. The fourth passivation layer PSV4 may include a same material as any one of the first to third passivation layers PSV1 to PSV3, but embodiments are not limited thereto.

On the fourth passivation layer PSV4, the first light conversion pattern CCP1 may be disposed in the eighth opening OP8.

The first light conversion pattern CCP1 may include color conversion particles and/or light scattering particles. The color conversion particles may convert incident light into light of another color by changing a wavelength of the incident light. Also, the color conversion particles may scatter incident light. In embodiments, the color conversion particles may be quantum dots. The light scattering particles may scatter incident light.

The first sub-pixel SP1 may be a red sub-pixel. In case that the first light emitting element LD1 emits light of a blue color, the first light conversion pattern CCP1 may include first color conversion particles QD1 configured to convert light of the blue color into light of a red color. In case that the first light emitting element LD1 emits light of the red color, the first light conversion pattern CCP1 may include light scattering particles. As such, the particles included in the first light conversion pattern CCP1 may be variously changed according to the first light emitting element LD1.

The low refractive layer LRL may be disposed on the second bank BNK2, the reflective layer RFL, and the first light conversion pattern CCP1. The low refractive layer LRL may have a refractive index lower than a refractive index of the first light conversion pattern CCP1. The low refractive layer LRL is configured to refract or totally reflect light according to an incident angle of the corresponding light. For example, the low refractive layer LRL may again provide light passing through the first light conversion pattern CCP1 to the first light conversion pattern CCP1. Accordingly, the light conversion efficiency of the first light conversion pattern CCP1 can be improved.

The color filter layer CFL may be disposed on the low refractive layer LRL. The color filter layer CFL may include a first color filter CF1 and light blocking patterns LBP. The first color filter CF1 overlaps the first light conversion pattern CCP1. The first color filter CF1 may allow light in a desired wavelength range to be selectively transmitted therethrough. In case that the first sub-pixel SP1 is a red sub-pixel, the first color filter CF1 may include a red color filter. The light blocking patterns LBP may include at least one of various kinds of light blocking materials.

In the above, the first light emitting element LD1 of the first sub-pixel SP1 has been described. Each of the second and third sub-pixels SP2 and SP3 shown in FIG. 6 may also include a light emitting element configured similarly to the first light emitting element LD1 in a range in which it is not differently described herein.

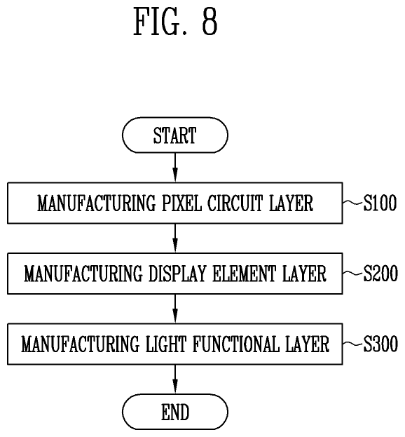

Hereinafter, a method of manufacturing a display device DD in accordance with an embodiment of the disclosure will be described with reference to FIGS. 8 to 16. In FIGS. 8 to 16, descriptions of portions overlapping the above-described portions will be simplified or will not be repeated.

FIG. 8 is a schematic flowchart illustrating a method of manufacturing a display device in accordance with an embodiment of the disclosure.

Referring to FIG. 8, the method of manufacturing the display device DD in accordance with the embodiment of the disclosure may include step S100 of manufacturing a pixel circuit layer, step S200 of manufacturing a display element layer, and step S300 of manufacturing a light functional layer.

Referring to FIGS. 7 and 8, in the step S100 of manufacturing the pixel circuit layer, a pixel circuit layer PCL may be disposed on a substrate SUB.

In an embodiment, a conductive layer or an insulating layer on the substrate SUB may be formed based on an ordinary process for manufacturing a semiconductor device. For example, the conductive layer or the insulating layer on the substrate SUB may be formed through a photolithography process, be etched through various processes (wet etching, dry etching, and the like), and be deposited through various processes (sputtering, chemical vapor deposition, and the like within the spirit and the scope of the disclosure). However, the disclosure is not necessarily limited.

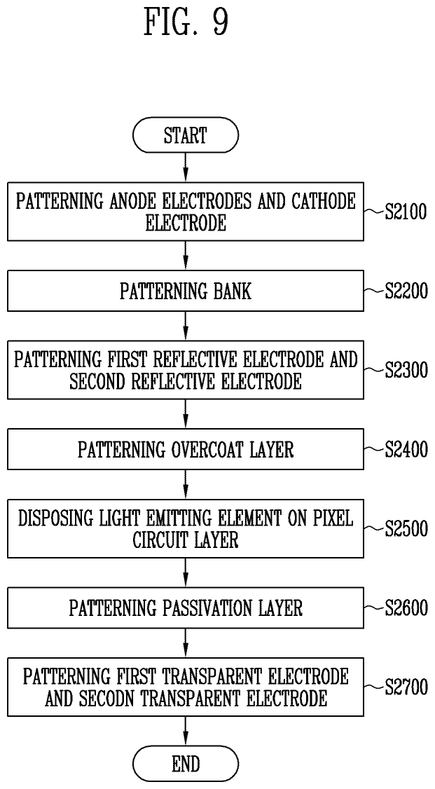

Referring to FIGS. 7 and 8, in the step S200 of manufacturing the display element layer, a first light emitting element LD1 may be disposed on the pixel circuit layer PCL. This will be described in more detail later together with FIG. 9.

Referring to FIGS. 7 and 8, in the step S300 of manufacturing the light functional layer, a light functional layer LFL may be disposed on a display element layer DPL. In this step S300, layers for forming the light functional layer LFL may be sequentially formed on the display element layer DPL. For example, referring to FIG. 7, a second bank BNK2, a reflective layer RFE, a fourth passivation layer PSV4, a first light conversion pattern CCP1, a low refractive layer, and a color filter layer CFL may be formed on a capping layer CPL.

FIG. 9 is a schematic flowchart illustrating the step of manufacturing the display element layer in accordance with an embodiment of the disclosure.

Referring to FIGS. 8 and 9, the step S200 of manufacturing the display element layer may include step S2100 of patterning anode electrodes and a cathode electrode, step S2200 of patterning a bank, step S2300 of patterning first reflective electrode and second reflective electrode, step S2400 of patterning an overcoat layer, step S2500 of disposing a light emitting element on the pixel circuit layer, step S2600 of patterning a passivation layer, and step S2700 of patterning a first transparent electrode and a second transparent electrode.

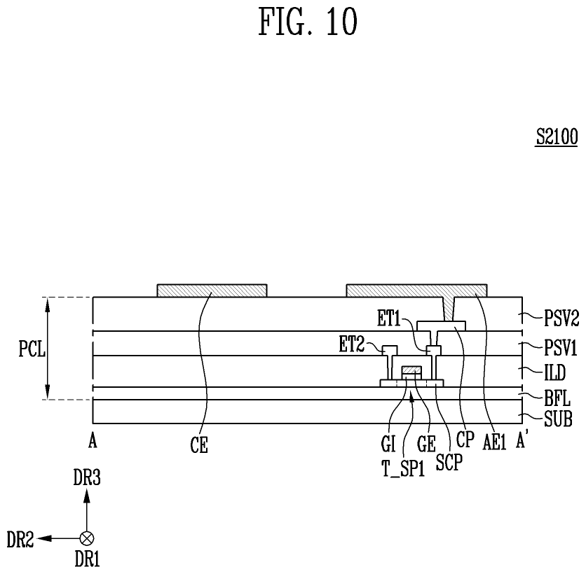

FIGS. 10 to 16 are schematic sectional views illustrating process steps according to the step shown in FIG. 9. For convenience of descriptions, FIGS. 10 to 16 schematically illustrate an area corresponding to the sectional structure described above with reference to FIGS. 6 and 7.

Referring to FIGS. 9 and 10, in the step S2100 of patterning the anode electrodes and the cathode electrode, a first anode electrode AE1 and a cathode electrode CE may be formed on the pixel circuit layer PCL (or the substrate SUB). Also, in this step S2100, a second anode electrode and a third anode electrode may be formed.

In this step S2100, in case that the first anode electrode AE1 is formed, a contact hole penetrating a second passivation layer PSV2 may be formed. Accordingly, the first anode electrode AE1 may be electrically connected to a transistor T_SP1.

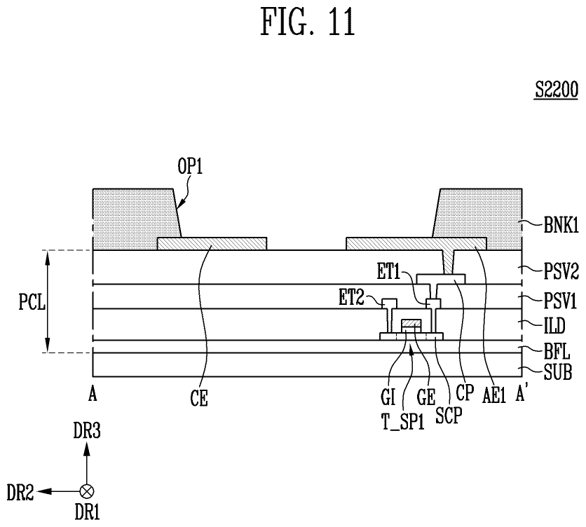

Referring to FIGS. 9 and 11, in the step S2200 of patterning the bank, a first bank BNK1 may be formed on the pixel circuit layer PCL (or the substrate SUB).

In this step S2200, the first bank BNK1 surrounding each of two or more areas may be patterned to form a first opening OP1. For example, the first bank BNK1 may expose a portion of the cathode electrode CE, and expose a portion of the first anode electrode AE1. However, in embodiments, this step S2200 may be omitted.

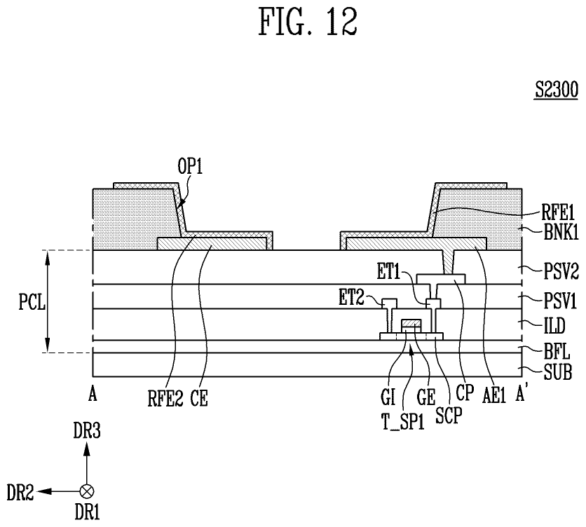

Referring to FIGS. 9 and 12, in the step S2300 of patterning the first reflective electrode and the second reflective electrode, a first reflective electrode RFE1 may be disposed on the exposed portion of the first anode electrode AE1 and a side surface of the first bank BNK1, which is adjacent thereto. A second reflective electrode RFE2 may be disposed on the exposed portion of the cathode electrode CE and a side surface of the first bank BNK1, which is adjacent thereto.

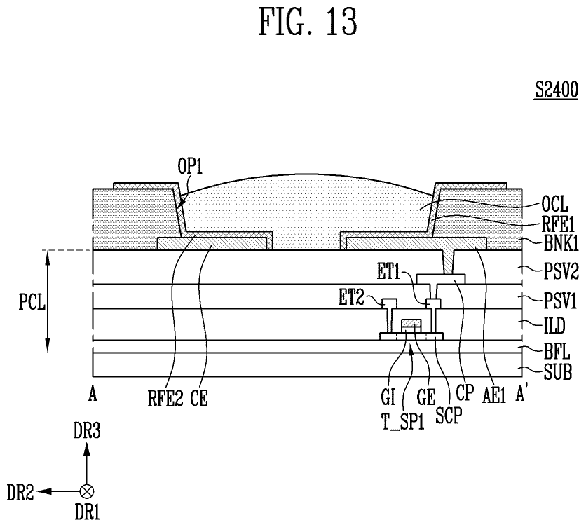

Referring to FIGS. 9 and 13, in the step S2400 of patterning the overcoat layer, an overcoat layer OCL may be disposed in the first opening OP1 of the first bank BNK1 on the first and second reflective electrodes RFE1 and RFE2 and the second passivation layer PSV2.

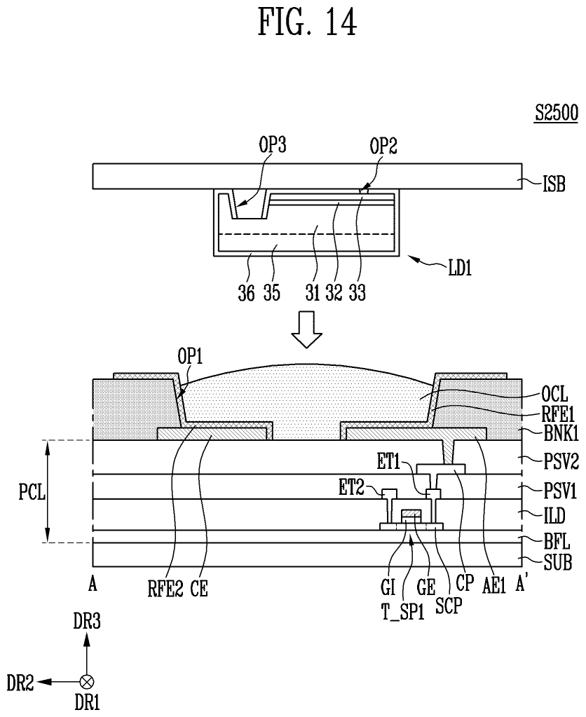

Referring to FIGS. 9 and 14, in the step S2500 of disposing the light emitting element on the pixel circuit layer, a first light emitting element LD1 may be disposed on the overcoat layer OCL.

In embodiments, the first light emitting element LD1 may be disposed on the overcoat layer OCL in a state in which the first light emitting element LD1 is disposed on an upper substrate ISB. The first light emitting element LD1 may include a second opening OP2 and a third opening OP3. The second opening OP2 and the third opening OP3 may be disposed to face in the same direction. For example, the second opening OP2 and the third opening OP3 may face in the third direction DR3.

A top surface of the first light emitting element LD1 may be connected to the upper substrate ISB. For example, the upper substrate ISB may be an interposer substrate. In embodiments, an insulative film 36 disposed at an upper portion of the light emitting element LD1 and the upper substrate ISB may be in direct contact with each other.

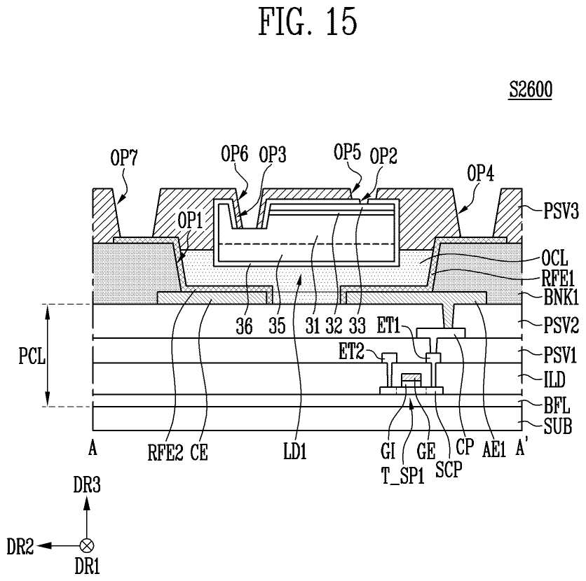

Referring to FIGS. 9 and 15, in the step S2600 of patterning the passivation layer, a third passivation layer PSV3 including fourth to seventh openings OP4 to OP7 may be patterned. The third passivation layer PSV3 may be disposed on the first and second reflective electrodes RFE1 and RFE2, the first light emitting element LD1, and the overcoat layer OCL. Also, the third passivation layer PSV3 may be disposed on the insulative film 36 adjacent to the third opening OP3.

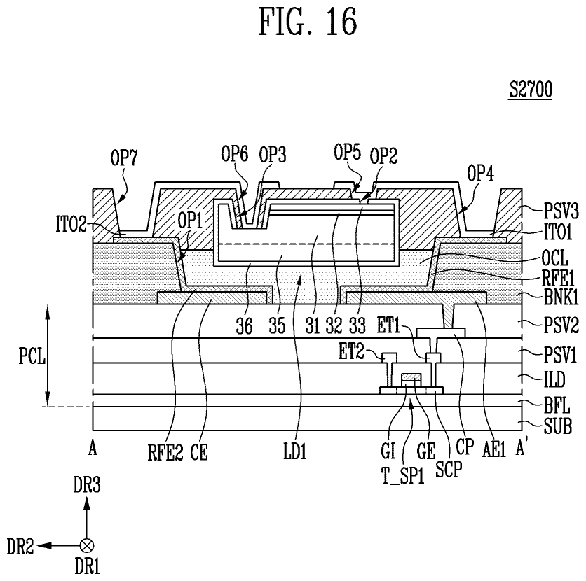

FIGS. 9 and 16, in the step S2700 of patterning the first transparent electrode and the second transparent electrode, first and second transparent electrodes ITO1 and ITO2 may be disposed on the third passivation layer PSV3.

The first transparent electrode ITO1 may electrically connect the first reflective electrode RFE1 exposed by the fourth opening OP4 to a second semiconductor layer 33 of the first light emitting element LD1, which is exposed by the second opening OP2 and the fifth opening OP5.

The second transparent electrode ITO2 may electrically connect the second reflective electrode RFE2 exposed by the seventh opening OP7 to a first semiconductor layer 31 of the first light emitting element LD1, which is exposed by the third opening OP3 and the sixth opening OP6.

As the third passivation layer PSV3 is disposed on the insulative film 36 adjacent to the third opening OP3 in the step S2500, the third passivation layer PSV3 can block a path of a leakage current caused by cracks even in case that the cracks are generated in the third opening OP3. Accordingly, although the second transparent electrode ITO2 is disposed in the sixth opening OP6 in this step S2600, the leakage current caused by the cracks does not flow through the second transparent electrode ITO2. For example, a defect of the display device, which is caused by the leakage current, can be decreased.

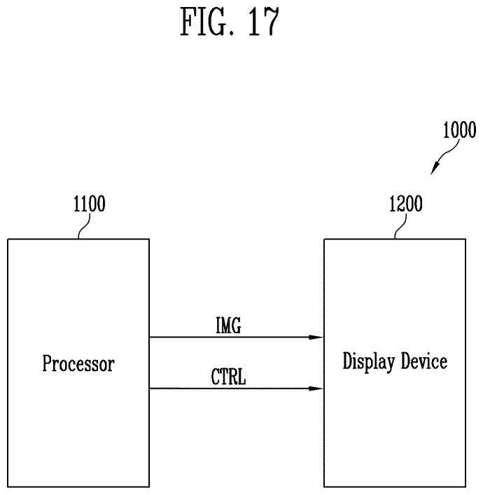

FIG. 17 is a block diagram illustrating an embodiment of a display system.

Referring to FIG. 17, the display system 1000 may include a processor 1100 and a display device 1200.

The processor 1100 may perform various tasks and various calculations. In embodiments, the processor 1100 may include an Application Processor (AP), a Graphics Processing Unit (GPU), a microprocessor, a Central Processing Unit (CPU), and the like within the spirit and the scope of the disclosure. The processor 1100 may be connected to other components of the display system 1000 through a bus system to control the components of the display system 1000.

The processor 1100 may transmit image data IMG and a control signal CTRL to the display device 1200. The display device 1200 may display an image, based on the image data IMG and the control signal CTRL. The display device 1200 may be configured identical to the display device DD described with reference to FIG. 1. The image data IMG and the control signal CTRL may be provided as the input image data IMG and the control signal CTRL, which are shown in FIG. 1, respectively.

The display system 1000 may include a computing system for providing an image display function, such as a smart watch, a mobile phone, a smartphone, a portable computer, a tablet personal computer (PC), a watch phone, an automotive display, a smart glass, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

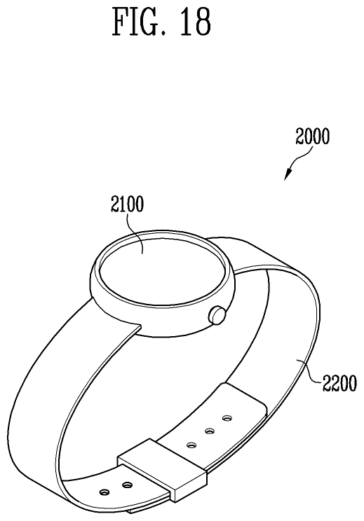

FIGS. 18 to 21 are schematic perspective views illustrating application examples of the display system shown in FIG. 17.

Referring to FIG. 18, the display system 1000 shown in FIG. 17 may be applied to a smart watch 2000 including a display part 2100 and a strap part 2200.

The smart watch 2000 may be a wearable electronic device. For example, the smart watch 2000 may have a structure in which the strap part 2200 is mounted on a wrist of a user. The display system 1000 and/or the display device 1200 may be applied to the display part 2100, so that image data including time information can be provided to the user.

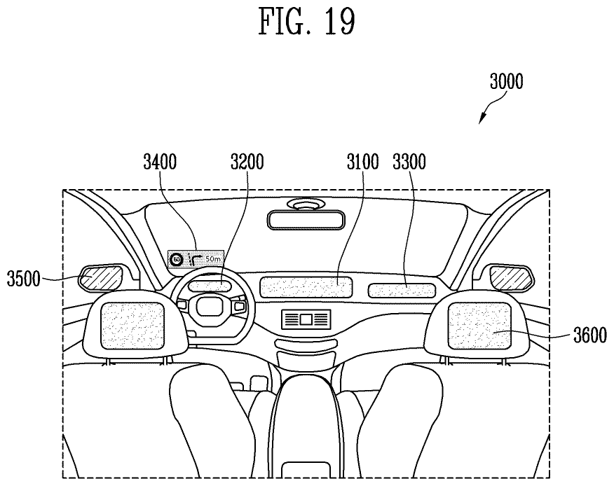

Referring to FIG. 19, the display system 1000 shown in FIG. 17 may be applied to an automotive display system 3000. The automotive display system 3000 may include a computing system provided at the inside/outside of a vehicle to provide image data.

For example, the display system 1000 and/or the display device 1200 may be applied to at least one of an infortainment panel 3100, a cluster 3200, a co-driver display 3300, a head-up display 3400, a side mirror display 3500, and a rear seat display 3600, which are provided in the vehicle.

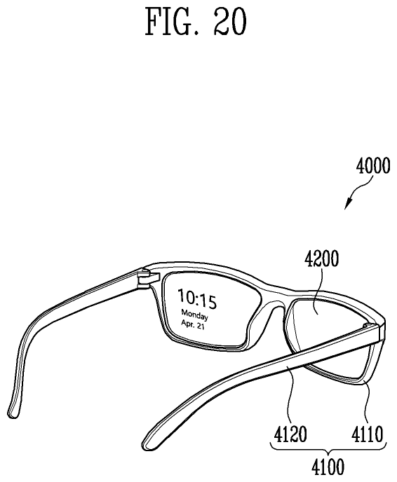

Referring to FIG. 20, the display system 1000 shown in FIG. 17 may be applied to smart glasses 4000. The smart glasses 4000 are a wearable electronic device which can be worn on the face of a user. For example, the smart glasses 4000 may be a wearable device for Augmented Reality (AR).

The smart glasses 4000 may include a frame 4100 and a lens part 4200. The frame 4100 may include a housing 4110 supporting the lens part 4200 and a leg part 4120 for allowing the user to wear the smart glasses 4000. The leg part 4120 may be connected to the housing 4110 through a hinge, to be folded or unfolded with respect to the housing 4110.

A battery, a touch pad, a microphone, a camera, and the like may be built in the frame 4100. A projector for outputting light, a processor for controlling a light signal, and the like may be built in the frame 4100.

The lens part 4200 may be an optical member which allows light to be transmitted therethrough or allows light to be reflected thereby. For example, the lens part 4200 may include glass, transparent synthetic resin, and the like within the spirit and the scope of the disclosure.

In order to enable eyes of the user to recognize visual information, the lens part 4200 may allow an image caused by a light signal transmitted from the projector of the frame 4100 to be reflected by a rear surface (for example, a surface in a direction facing the eyes of the user) of the lens part 4200. For example, the user may recognize information including time, data, and the like, which are displayed on the lens part 4200. The projector and/or the lens part 4200 may be a kind of display device. The display device 1200 may be applied to the projector and/or the lens part 4200.

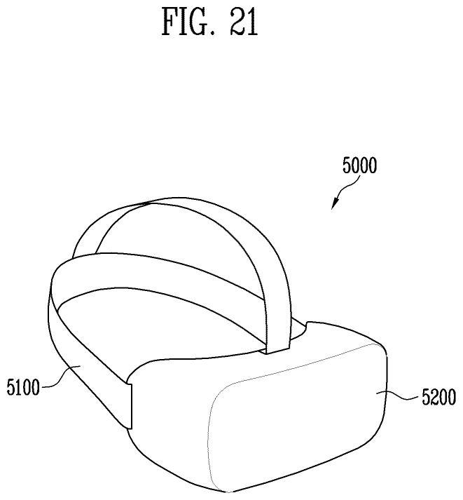

Referring to FIG. 21, the display system 1000 shown in FIG. 17 may be applied to a head mounted display device 5000.

The head mounted display device 5000 may be a wearable electronic device which can be worn on the head of a user. For example, the head mounted display device 5000 may be a wearable device for virtual reality (VR) or mixed reality (MR).

The head mounted display device 5000 may include a head mounted band 5100 and a display device accommodating case 5200. The head mounted band 5100 may be connected to the display device accommodating case 5200. The head mounted band 5100 may include a horizontal band and/or a vertical band, used to fix the head mounted display device 5000 to the head of the user. The horizontal band may be configured to surround a side portion of the head of the user, and the vertical band may be configured to surround an upper portion of the head of the user. However, embodiments are not limited thereto. For example, the head mounted band 5100 may be implemented in the form of a glasses frame, a helmet or the like within the spirit and the scope of the disclosure.

The display device accommodating case 5200 may accommodate the display system 1000 and/or the display device 1200.

In the display device in accordance with the disclosure, a path through which a leakage current flows is blocked inside a light emitting element, so that a dark spot defect can be reduced or prevented.

Example embodiments have been disclosed herein, and although terms are employed, they are used and are to be interpreted in a generic and descriptive sense only and not for purpose of limitation. In some instances, as would be apparent to one of ordinary skill in the art, features, characteristics, and/or elements described in connection with a given embodiment may be used singly or in combination with features, characteristics, and/or elements described in connection with other embodiments unless otherwise indicated. Accordingly, it will be understood by those of skill in the art that various changes in form and details may be made without departing from the spirit and scope of the disclosure and as set forth in the following claims.

What is claimed is:

1. A display device comprising:
a display element layer disposed on a substrate,
wherein the display element layer includes:
an anode electrode and a cathode electrode;
a first reflective electrode disposed on the anode electrode;
a second reflective electrode disposed on the cathode electrode;
a light emitting element including a first semiconductor layer, a second semiconductor layer, and an insulative film;
a first transparent electrode directly electrically connecting the second semiconductor layer to the first reflective electrode; and
a second transparent electrode directly electrically connecting the first semiconductor layer to the second reflective electrode.

2. The display device of claim 1, wherein
the insulative film includes a first opening and a second opening, and
the second semiconductor layer is exposed in the first opening, and the first semiconductor layer is exposed in the second opening.

3. The display device of claim 2, wherein the first opening and the second opening face in a same direction.

4. The display device of claim 2, further comprising:
a passivation layer disposed on the first reflective electrode, the second reflective electrode, an inside of the second opening, and the light emitting element,
wherein the passivation layer directly contacts the insulative film in the second opening.

5. The display device of claim 4, wherein the passivation layer includes a third opening overlapping the first opening and a fourth opening disposed inside of the second opening.

6. The display device of claim 5, wherein
the first transparent electrode and the second transparent electrode are disposed on the passivation layer,
the first transparent electrode directly contacts the second semiconductor layer exposed by the first opening and the third opening, and
the second transparent electrode directly contacts the first semiconductor layer exposed by the second opening and the fourth opening.

7. The display device of claim 6, wherein
the first semiconductor layer includes at least one n-type semiconductor layer, and
the second semiconductor layer includes at least one p-type semiconductor layer.

8. The display device of claim 7, wherein the insulative film covers an outer circumferential surface of a light emitting stack structure in which the first semiconductor layer and the second semiconductor layer are stacked.

9. A method of manufacturing a display device, the method comprising:
manufacturing a pixel circuit layer disposed on a substrate; and
manufacturing a display element layer disposed on the pixel circuit layer,
wherein the manufacturing of the display element layer includes:
patterning an anode electrode and a cathode electrode on the pixel circuit layer;
patterning a first reflective electrode electrically connected to the anode electrode and a second reflective electrode electrically connected to the cathode electrode;
disposing, on the pixel circuit layer, a light emitting element including a first semiconductor layer, a second semiconductor layer, and an insulative film including a first opening and a second opening; and
patterning a passivation layer on the first reflective electrode, the second reflective electrode, an inside of the second opening, and the light emitting element.

10. The method of claim 9, wherein
the second semiconductor layer is exposed in the first opening, and
the first semiconductor layer is exposed in the second opening.

11. The method of claim 10, wherein the passivation layer and the insulative film directly contact each other in the second opening.

12. The method of claim 11, comprising:
patterning, on the passivation layer, a first transparent electrode directly electrically connecting the second semiconductor layer to the first reflective electrode and a second transparent electrode directly electrically connecting the first semiconductor layer to the second reflective electrode.

13. The method of claim 12, wherein
the disposing of the light emitting element on the pixel circuit layer includes disposing the light emitting element on the pixel circuit layer in which the light emitting element is disposed on an upper substrate, and
the insulative film disposed at an upper portion of the light emitting element directly contacts the upper substrate.

14. The method of claim 12, wherein
the first semiconductor layer includes at least one n-type semiconductor layer, and
the second semiconductor layer includes at least one p-type semiconductor layer.

15. The method of claim 14, wherein the insulative film covers an outer circumferential surface of a light emitting stack structure in which the first semiconductor layer and the second semiconductor layer are stacked.

16. An electronic device comprising:
a display device including a display element layer disposed on a substrate,
wherein the display element layer includes:
an anode electrode and a cathode electrode;
a first reflective electrode disposed on the anode electrode;
a second reflective electrode disposed on the cathode electrode;
a light emitting element including a first semiconductor layer, a second semiconductor layer, and an insulative film;
a first transparent electrode directly electrically connecting the second semiconductor layer to the first reflective electrode; and
a second transparent electrode directly electrically connecting the first semiconductor layer to the second reflective electrode.

17. The electronic device of claim 16, wherein the electronic device is at least one of a smart watch, a mobile phone, a smartphone, a portable computer, a tablet personal computer (PC), a watch phone, an automotive display, a smart glass, a portable multimedia player (PMP), a navigation system, an ultra mobile computer (UMPC), a head mounted display (HMD) device, a virtual reality (VR) device, a mixed reality (MR) device, and an augmented reality (AR) device.
